(19) United States
(12) Patent Application Publication
(10) Pub. No.: US 2019/0196288 A1
(43) Pub. Date: Jun. 27, 2019

(54) ARRAY SUBSTRATE AND METHOD OF MANUFACTURING THE SAME, LIQUID CRYSTAL DISPLAY PANEL AND DISPLAY DEVICE

(71) Applicants: CHONGQING BOE OPTOELECTRONICS TECHNOLOGY CO., LTD., Chongqing (CN); BOE TECHNOLOGY GROUP CO., LTD., Beijing (CN)

(72) Inventors: Zhicai Xu, Beijing (CN); Ruilin Bi, Beijing (CN); Jiandong Guo, Beijing (CN); Zhulin Liu, Beijing (CN); Shouqiang Zhang, Beijing (CN); Kui Zhang, Beijing (CN)

(21) Appl. No.: 16/328,719

(22) PCT Filed: Feb. 13, 2018
(86) PCT No.: PCT/CN2018/076657

§ 371 Date: Feb. 26, 2019

(30) Foreign Application Priority Data
May 4, 2017 (CN) 201710309241.8

(51) Int. Cl. G02F 1/1362; H01L 27/12; G02F 1/1333; G02F 1/1335; G09G 3/36

(52) U.S. Cl. CPC G02F 1/136286; H01L 27/124; G02F 2001/136222; G02F 1/133512; G09G 3/3648; G02F 1/133305

(57) ABSTRACT

Embodiments of the present disclosure provide an array substrate, a method of manufacturing the same, a liquid crystal display panel, and a display device. The array substrate includes: a base substrate, a data line disposed on the base substrate and a pixel electrode layer disposed on a layer in which the data line is located. The pixel electrode layer includes a plurality of columns of pixel electrodes that are spaced apart from one another. An orthographic projection of the data line on the base substrate covers an orthographic projection of a gap between two adjacent columns of pixel electrodes on the base substrate, and a width of the data line is greater than a width of the gap between two adjacent columns of pixel electrodes.

### CROSS-REFERENCE TO RELATED APPLICATION

This application claims the benefit of Chinese Patent Application No. 201710309241.8, titled of “array substrate and method of manufacturing the same, liquid crystal display panel and display device”, filed with the State Intellectual Property Office of China on May 4, 2017, the whole disclosure of which is incorporated herein by reference.

### TECHNICAL FIELD

Embodiments of the present disclosure relate to field of display technology, and particularly, to an array substrate and a method of manufacturing the same, a liquid crystal display panel and a display device.

### DESCRIPTION OF RELATED ART

Liquid crystal display (LCD) panel has advantages such as light weight, thin thickness, low power consumption, ease of being driven, absence of baneful radiation and etc. and thus is widely used in a television, a notebook computer, a mobile phone, a personal digital assistant and others modern information apparatus and has a broad prospects of development. For a personal user, a curved display may bring a better display effect and vision experiment than a flat panel display, and thus becomes an important development direction of a liquid display panel.

A twisted nematic (TN) liquid crystal display panel is obtained by rotation by 90 degrees of liquid crystal between an array substrate and an opposite substrate. In a liquid crystal display panel working in a normally-white display mode, light leakage in a non-display region will degrade the contrast of an image when a black picture is displayed by the display panel. By contrast, a twisted nematic liquid crystal display panel may avoid light leakage in a normally-white display mode, which brings it to a dominant position in curved display field.

### SUMMARY

Embodiments of the present disclosure provide an array substrate including a base substrate, a data line disposed above the base substrate and a pixel electrode layer disposed on a layer in which the data line is located; wherein

the pixel electrode layer includes a plurality of columns of pixel electrodes that are spaced apart from one another; and

an orthographic projection of the data line on the base substrate covers an orthographic projection of a gap between two adjacent columns of pixel electrodes on the base substrate, and a width of the data line is greater than a width of the gap between the two adjacent columns of pixel electrodes.

In an embodiment, the orthographic projection of the data line on the base substrate partially covers the orthographic projection of the gap between the two adjacent columns of pixel electrodes on the base substrate.

In an embodiment, the orthographic projection of the data line on the base substrate overlaps with orthographic projections of the two adjacent columns of pixel electrodes on the base substrate respectively in overlapping regions having a same width.

In an embodiment, the array substrate further includes a color filter layer disposed between the layer in which the data line is located and the pixel electrode layer.

In an embodiment, the array substrate further includes a planarization layer between the color filter layer and the pixel electrode layer.

In an embodiment, the array substrate further includes a gate line extending in a first direction and disposed between the base substrate and the layer in which the data line is located; and a plurality of first common electrode lines and a plurality of second common electrode lines that are arranged in a same layer as the gate line, wherein the plurality of first common electrode lines extend in the first direction, the plurality of second common electrode lines extend in a second direction, and the first direction is perpendicular to the second direction.

In an embodiment, the second common electrode lines are in one-to-one correspondence with the plurality of columns of pixel electrodes; and

an orthographic projection of each of the second common electrode lines on the base substrate is located on a central line of an orthographic projection of a corresponding column of pixel electrodes on the base substrate.

An embodiment of the present disclosure provides a liquid crystal display panel including: the above mentioned array substrate and an opposite substrate disposed to be opposite to the array substrate.

In an embodiment, the liquid crystal display panel further includes a black matrix disposed on a side of the opposite substrate facing the array substrate; or

the liquid crystal display panel further includes a black matrix disposed on a side of the array substrate facing the opposite substrate, and the array substrate further includes the color filter layer disposed between the layer in which the data line is located and the pixel electrode layer, the black matrix being located in the gap between two adjacent color filter of the color filter layer.

An embodiment of the present disclosure provides a display device comprising the above mentioned liquid crystal display panel.

An embodiment of the present disclosure provides a method of manufacturing the above described array substrate, the method including:

providing the base substrate;

forming the data line on the base substrate; and

forming the pixel electrode layer including the plurality of columns of pixel electrodes that are spaced apart from one another on the layer in which the data line is located; wherein

the orthographic projection of the data line on the base substrate covers an orthographic projection of the gap between the two adjacent columns of pixel electrodes on the base substrate, and the width of the data line is greater than the width of the gap between the two adjacent columns of pixel electrodes.

In an embodiment, in the method according to the embodiment of the present disclosure, the method further includes: before the forming the pixel electrode layer including the plurality of columns of pixel electrodes,

forming a color filter layer on the layer in which the data line is located.

In an embodiment, in the method according to the embodiment of the present disclosure, the method further includes: before the forming the pixel electrode layer including the plurality of columns of pixel electrodes and after the forming the color filter layer,

forming a planarization layer on the color filter layer.

In an embodiment, in the method according to the embodiment of the present disclosure, before the forming the data line on the base substrate, the method further comprises:

simultaneously forming, on the base substrate, a gate line extending in the first direction and a plurality of first common electrode lines extending in the first direction and a plurality of second common electrode lines extending in a second direction, the first direction being perpendicular to the second direction;

the second common electrode lines are in one-to-one correspondence with the respective columns of pixel electrodes; and

an orthographic projection of each of the second common electrode lines on the base substrate is located on a central line of an orthographic projection of a corresponding column of pixel electrodes on the base substrate.

### BRIEF DESCRIPTION OF THE DRAWINGS

FIG. 1 is a structural schematic view of an array substrate according to an embodiment of the present disclosure;

FIG. 2 is a schematic view illustrating relative position relationship between a second common electrode line and a pixel electrode in an array substrate according to an embodiment of the present disclosure;

FIG. 3 illustrates a process of manufacturing an array substrate according to an embodiment of the present disclosure;

FIGS. 4a˜4g are schematic view illustrating structures obtained by respective step of the process of manufacturing an array substrate, as shown in FIG. 3; and

FIG. 5 is a structural schematic view of a liquid crystal display panel according to an embodiment of the present disclosure.

### DETAILED DESCRIPTION

In related art, for a curved liquid crystal display panel technology, the liquid crystal display panel needs to be bent. When being bent, the array substrate and the opposite substrate of a liquid crystal display panel tend to shift and thus may result in occurrence of light leakage in the liquid crystal display panel. In addition, the size of a black matrix is increased to prevent the light leakage, which, however, reduces the aperture ratio of the liquid crystal display panel.

Embodiments of an array substrate and a method of manufacturing the same, a liquid crystal display panel and a display device according to the present disclosure will be described in detail in combination with the drawings.

Shapes and sizes of the layers shown in the drawings do not reflect a real scale of the array substrate or the liquid crystal display panel and are merely intended to schematically illustrate the content of the present disclosure.

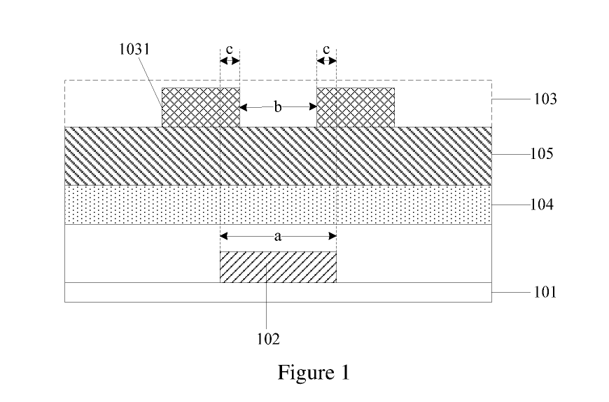

An embodiment of the present disclosure provides an array substrate, as shown in FIG. 1, including: a base substrate 101, a data line 102 disposed on the base substrate 101 and a pixel electrode layer 103; wherein,

the pixel electrode layer 103 includes a plurality of columns of pixel electrodes 1031 that are spaced apart from one another;

an orthographic projection of the data line 102 on the base substrate 101 covers an orthographic projection of a gap between two adjacent columns of pixel electrodes on the base substrate 101, and a width a of the data line 102 is greater than a width b of the gap between two adjacent columns of pixel electrodes.

In the above array substrate according to the embodiment of the present disclosure, as the orthographic projection of the data line 102 on the base substrate 101 covers the orthographic projection of the gap between two adjacent columns of pixel electrodes on the base substrate 101, and the width a of the data line 102 is greater than the width b of the gap between two adjacent columns of pixel electrodes, an electric field is formed between the data line 102 and the pixel electrode 1031 with longitudinal electric field lines having a direction directed from the array substrate to an opposite substrate, such that light leakage along a direction in which the data line extends may be prevented by controlling torsion of liquid crystal near an edge of the pixel electrode. Meanwhile, with this configuration, no black matrix or other types of light shielding components for shielding light is needed to prevent light from leaking, which effectively increases aperture ratio.

In the array substrate according to an embodiment of the present disclosure, the base substrate 101 may be a flexible base substrate, such as a plastic base plate with properties of good heat resistance and durability and made of, for example, polyvinylether phthalate, polyethylene naphthalate, polycarbonate, polyarylate, polyetherimide, polyethersulfone or polyimide. The base substrate 101 may also be a rigid base substrate, such as a glass base plate, and is not limited herein.

In an embodiment of the present disclosure, the orthographic projection of the data line 102 on the base substrate 101 may partially cover the orthographic projections of the two adjacent columns of pixel electrodes on the base substrate 101 such that a normal display will not be affected.

In an embodiment of the present disclosure, as shown in FIG. 1, the orthographic projection of the data line 102 on the base substrate 101 may overlap with the orthographic projections of the two adjacent columns of pixel electrodes on the base substrate 101 respectively in overlapping regions having a same width c.

In an embodiment of the present disclosure, the orthographic projection of the data line 102 on the base substrate 101 may overlap with the orthographic projections of the two adjacent columns of pixel electrodes on the base substrate 101 respectively in overlapping regions having different widths, which is not limited herein.

Generally, a charging process of the pixel electrode 1031 by the data line 102 requires to a stable voltage for a time period. In an embodiment of the present disclosure, the overlapping regions of the orthographic projection of the data line 102 on the base substrate 101 with the orthographic projections of the two adjacent columns of pixel electrodes 1031 on the base substrate 101 may result in a capacitance being generated between the data line 102 and the overlapping regions, which capacitance may cause adverse affection on the voltage stablilization on the pixel electrode 1031 to some extent and thus in turn cause negative influence on display performance. The array substrate according to an embodiment of the disclosure further may include: a color filter layer 104 disposed between the layer in which the data line 102 is located and the pixel electrode layer 103. With this configuration, a distance between the data line 102 and the pixel electrode 1031 is increased so as to reduce the capacitance between them, reducing risk of interruption on the voltage stablilization on the pixel electrode 1031 due to the capacitance therebetween. In addition, configuration of the color filter layer 104 on the array substrate may also avoid not-strict-alignment between the color filter layer 104 and the pixel electrode 1031 and thus may increase aperture ratio of a liquid crystal display panel and thus increase brightness of the liquid crystal display panel.

In an embodiment of the present disclosure, the array substrate may further include a planarization layer 105 between the color filter layer 104 and the pixel electrode layer 103 so as to further increase the distance between the data line 102 and the pixel electrode 1031 and thus further reduce the capacitance between them.

Generally, the color filter layer 10 includes a plurality of color filters with different colors. During manufacturing, an overlapping region may be formed between any two adjacent color filters such that a step or height difference is generated and thus the liquid crystal over the overlapping region will be in backward dislocation due to the step or height difference, which seriously affects display performance. In the embodiment, provision of the planarization layer 105 on the color filter layer 104 may reduce the step or height difference due to overlapping between any two adjacent color filters in the color filter layer 104 and thus enhance display quality.

In this embodiment, the planarization layer 105 may be made of polyacrylic resin, polyepoxy-acrylic resin, photosensitive polyimide resin, polyester acrylic resin, polyurethane acrylate resin, phenolic epoxy acrylic resin or other organic insulating material, which is not limited herein.

In an embodiment of the present disclosure, the array substrate may further include a thin film transistor, which specifically may be of a bottom-gate type structure or may be of a top-gate structure, which is not limited herein.

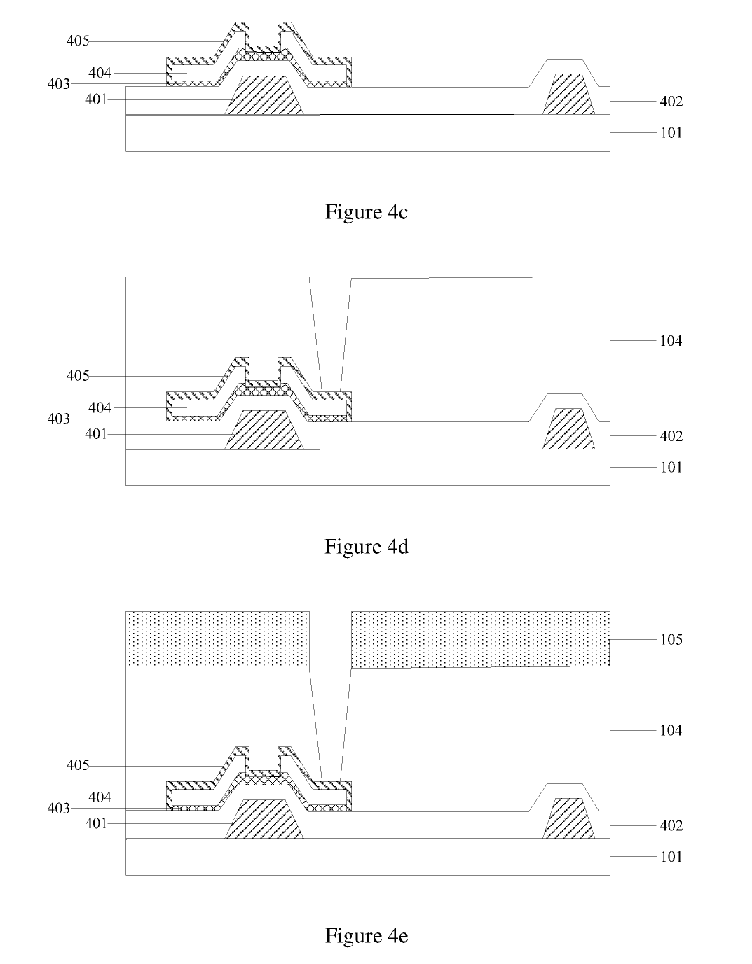

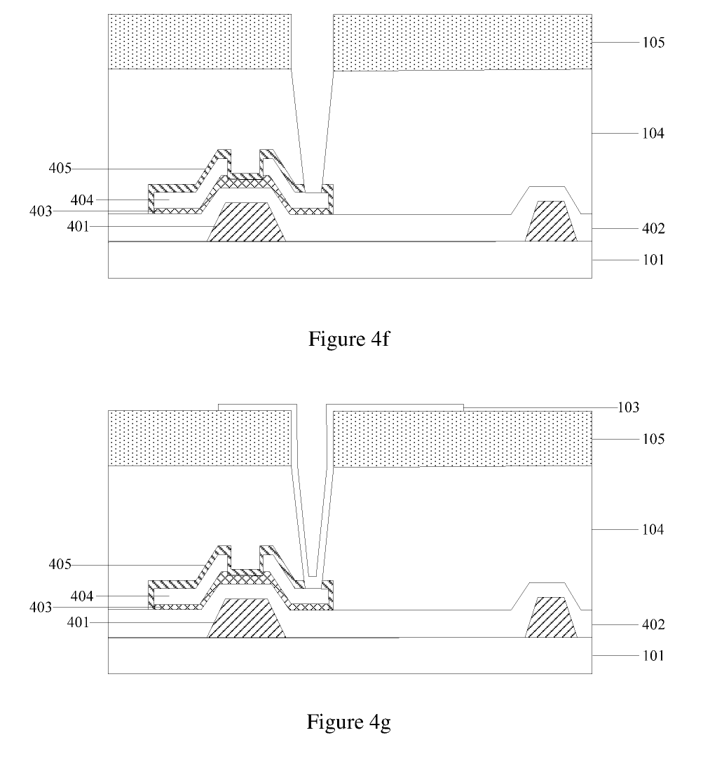

In an embodiment of the present disclosure, the thin film transistor of the array substrate is a bottom-gate thin film transistor, as shown in for example FIG. 4g. In the array substrate according to the embodiment, drain and source electrodes 404 are located over an active layer 403, a gate electrode 401 is located under the active layer 403, a gate insulating layer 402 is provided between the gate electrode 401 and the active layer 403, and a passivation layer 405 is provided over a layer in which the drain and source electrodes 404 are located. The array substrate may further include the color filter layer 104 on the gate insulating layer 402 and the planarization layer 105 on the color filter layer 104. The array substrate may further include the pixel electrode 1031 located over the drain and source electrodes 404 of the corresponding thin film transistor, and each pixel electrode 1031 is electrically connected with the drain electrode or source electrode 404 of the corresponding thin film transistor via a through hole penetrating through the passivation layer 405, the color filter layer 104 and the planarization layer 105.

In the embodiment, the gate electrode 401 and the drain and source electrodes 404 may be formed from materials including molybdenum, aluminum, tungsten, titanium, copper or an alloy combination thereof, which is not limited herein. The gate insulating layer 402 and the passivation layer 405 may be formed from materials including silicon oxide, silicon nitride or a combination thereof, which is not limited herein. The active layer 403 may be formed from a material including a polycrystalline silicon semiconductor material, an amorphous silicon semiconductor material, an oxide compound semiconductor material, or an organic semiconductor material, which is not limited herein.

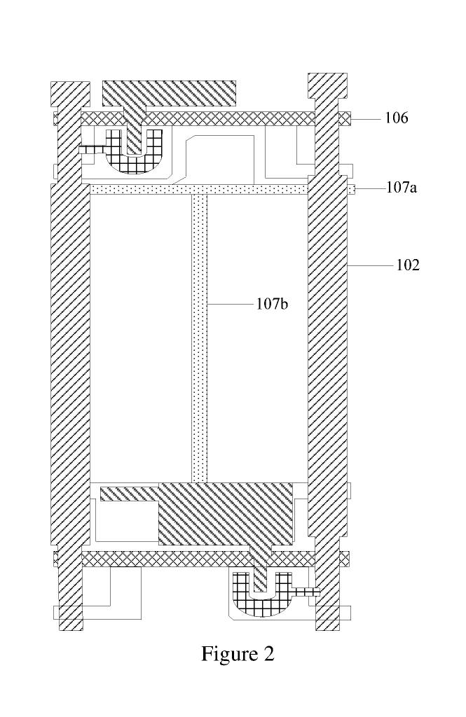

In practice, as shown in FIG. 2, the array substrate according to an embodiment of the present disclosure may further include: a gate line 106 extending in a first direction and disposed between the base substrate 101 and a layer in which the data line 102 is located; and a plurality of first common electrode lines 107a and second common electrode lines 107b that are arranged in the same layer as the gate line 106. In the embodiment, the gate line 106 is configured to provide a scan signal to each pixel electrode 1031 and extend in the first direction; the data line is configured to extend in a second direction, the second direction being substantially perpendicular to the first direction. The respective first common electrode lines 107a and second common electrode lines 107b are configured to provide a common voltage signal to a common electrode. In the embodiment as shown in FIG. 2, the first common electrode line 107a in the array substrate extends in the first direction, for example, in a horizontal direction, and the second common electrode line 107b extends in the second direction, for example, in a vertical direction.

According to the embodiment, the gate line 106, the first common electrode lines 107a and second common electrode lines 107b may be manufactured by a single patterning process so as to simplify process, save manufacturing cost, and increase production efficiency, or alternatively, may be manufactured by two patterning processes, which is not limited herein. In addition, the gate line 106, the first common electrode lines 107a and the second common electrode lines 107b may be made of molybdenum, aluminum, tungsten, titanium, copper or an alloy combination thereof, which is not limited herein.

According to an embodiment of the present disclosure, the drain and source electrodes 404 and the data line 102 may be manufactured by a single patterning process so as to simplify process, save manufacturing cost, and increase production efficiency, or alternatively, may be manufactured respectively by two patterning processes, which is not limited herein. In addition, the drain and source electrodes 404 and the data line 102 may be manufactured from molybdenum, aluminum, tungsten, titanium, copper or an alloy combination thereof, which is not limited herein.

In an embodiment of the present disclosure, in the array substrate, the second common electrode lines 107b are in one-to-one correspondence with the pixel electrodes so as to obtain uniformity in displayed image.

In an embodiment of the present disclosure, an orthographic projection of one of the second common electrode lines 107b on the base substrate 101 is located at a central line of an orthographic projection of a corresponding column of pixel electrodes on the base substrate 101. Referring to FIG. 2, a relative position relationship between the orthographic projection of one of the second common electrode lines 107b on the base substrate 101 and the orthographic projection of one pixel electrode 1031 of the corresponding column of pixel electrodes on the base substrate 101 is schematically illustrated.

With this configuration, obtained effective display areas that correspond to the pixel electrodes 1031 are symmetrical so as to increase uniformity of displayed image. Further, as the color filter layer 104 over a layer in which the second common electrode lines 107b are located is a relative thick, the second common electrode lines 107b will be not visible at a display side of the liquid crystal panel, that is, the aperture ratio of the liquid crystal panel will be not affected, even though the orthographic projection of the second common electrode lines 107b on the base substrate 101 were be at the central line of the orthographic projection of a corresponding column of pixel electrodes on the base substrate 101.

Correspondingly, embodiments of the present disclosure provide a method of manufacturing an array substrate. Embodiments of the method of manufacturing the array substrate may refer to the implementation of the array substrate that is provided according to the above embodiments and will not be repeatedly described as the principle of the method for solving problem is similar to that of the above described array substrate.

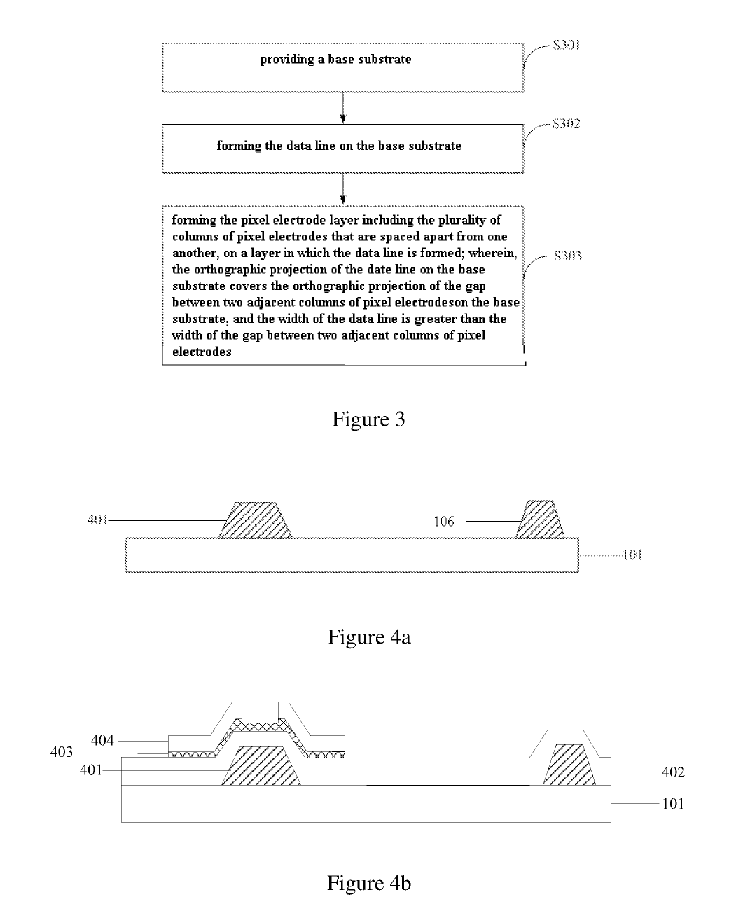

Specifically, embodiments of the present disclosure provide a method of manufacturing the above array substrate, as shown in FIG. 3. The method may specifically include the following steps:

S301: providing the base substrate;

S302: forming the data line on the base substrate;

S303: forming the pixel electrode layer including the plurality of columns of pixel electrodes that are spaced apart from one another, on a layer in which the data line is formed; wherein,

the orthographic projection of the date line on the base substrate covers the orthographic projection of the gap between two adjacent columns of pixel electrodes on the base substrate, and the width of the data line is greater than the width of the gap between two adjacent columns of pixel electrodes.

In practice, the above method provided by the embodiments of the present disclosure may further include: before forming the pixel electrode layer including the plurality of columns of pixel electrodes that are spaced apart from one another on the layer in which the data line is formed, forming the color filter layer on the layer in which the data line is formed, thereby reducing the capacitance between the data line and the pixel electrode.

Specifically, the above method provided by the embodiments of the present disclosure may further include: before forming the pixel electrode layer including the plurality of columns of pixel electrodes that are spaced apart from one another on the layer in which the data line is formed and after forming color filter layer on the layer in which the data line is formed, forming the planarization layer on the color filter layer, thereby further reducing the capacitance between the data line and the pixel electrode.

The above method provided by the embodiment of the present disclosure may further includes: before forming the data line on the base substrate, simultaneously forming the gate line extending in the first direction and a plurality of first common electrode lines extending in the first direction and a plurality of second common electrode lines extending in the second direction; wherein the second common electrode lines are in one-to-one correspondence with the pixel electrodes, and the orthographic projection of one of the second common electrode lines on the base substrate is located at the central line of the orthographic projection of a corresponding column of pixel electrodes on the base substrate, thereby increasing display uniformity of an image.

In order to understand the above method provided by the embodiments of the present disclosure better, embodiments of the present disclosure further provides structural schematic views for illustrating structures of the array substrate obtained after the steps of the above method, as shown in FIGS. 4a˜4g.

According to the embodiments of the present disclosure, the thin film transistor in the array substrate may be of a bottom-gate type structure or may be of a top-gate structure, which is not limited herein. Illustration will be made by an example of a thin film transistor with a bottom-gate structure.

The base substrate 101 is provided and patterns of the gate electrode 401 and the gate line 106 on the base substrate 101 is formed by a single patterning process, as shown in FIG. 4a, thereby simplifying manufacturing process of the array substrate and reducing times of using mask;

patterns of the gate insulating layer 402, the active layer 403, the drain and source electrodes 404 and the data line are formed in turn on the base substrate 101 on which the gate electrode 401 and the gate line 106 have been formed, as shown in FIG. 4b;

a pattern of the passivation layer 405 is formed on the layer in which the drain and source electrodes 404 and the data line are located, as shown in FIG. 4c;

a pattern of the color filter layer 104 having a through hole therein is formed on the passivation layer 405, as shown in FIG. 4d;

a pattern of the planarization layer 105 having a through hole that is communicated with the though hole in the color filter layer 104 is formed on the color filter layer 104, as shown in FIG. 4e;

a though hole is formed in the passivation layer 405 over the layer in which the drain and source electrodes 404 and the data line are located, as shown in FIG. 4f; and

a pattern of the pixel electrode layer 103 is formed on the planarization layer 105, wherein the pixel electrode 1031 is electrically connected with the corresponding drain electrode or source electrode 404 of the thin film transistor via the through hole penetrating through the passivation layer 405, the color filter layer 104 and the planarization layer 105, as shown in FIG. 4g.

It is noted that, in the method according to the above embodiments of the present disclosure, the patterning processes for forming the layers may include part of or all of processes of deposition, photoresist coating, masking by a mask, exposure, development, etching, peeling-off of the photoresist, and may also include others process procedures, which may be designed depending on a pattern to be formed by an actual manufacturing process, and is not limited herein. For example, a post-baking process may be included after development and before etching.

In an embodiment, the deposition process may include a chemical vapor deposition process, a plasma chemical vapor deposition process, or a physical vapor deposition process, which is not limited herein. Mask used in a masking process may be a Half Tone Mask, a Modified Single Mask, a Single Slit Mask or a Gray Tone Mask, which is not limited herein. The etching process may be a dry etching process or a wet etching process, which is not limited herein.

Based on the same inventive concept, embodiments of the present disclosure provide a liquid crystal display panel. Embodiments of the liquid crystal display panel may refer to the implementation of the above array substrate provided in embodiments of the present disclosure and will not be repeatedly described as the principle of the liquid crystal display panel for solving problem is similar to that of the above described array substrate.

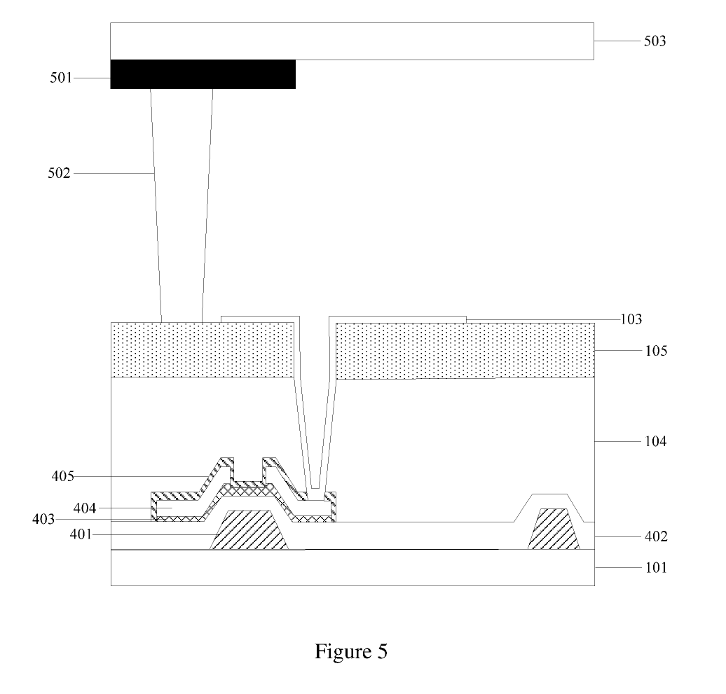

A liquid crystal display panel provided according to embodiments of the present disclosure, as shown in FIG. 5, includes the above array substrate and an opposite substrate configured to be opposite to the array substrate.

In an embodiment of the present disclosure, in order to prevent the color filter layer 104 from leaking light through a gap between any two adjacent color filters in the color filter layer 104, The liquid crystal display panel may further include a black matrix 501 configured on a side of the opposite substrate facing the array substrate, as shown in FIG. 5. Of course, in another embodiment of the present disclosure, the black matrix may be configured on a side of the array substrate facing the opposite substrate and is located at the gap between the color filters in the color filter layer.

In this embodiment, the black matrix 501 may not only prevent the color filter layer from leaking light from the gap between the color filters but also increase contrast between different colors. Generally, the black matrix 501 may be made of two types of materials, one of which is a metal film, such as an oxide film, and the other is resin-type black photoresist film and has a main material of carbon. In an embodiment, the black matrix 501 may be made of a metal film as the metal film may be easy to be etched to obtain line or path and has a good property of shielding light.

It is noted that in the above display panel provided by the embodiment of the present disclosure, in addition to make the black matrix 501 from the metal film or black resin material, the black matrix 501 may be obtained by overlapping a red-light color filter and a blue-light color filter to achieve effect of shielding light, which is not limited herein.

In an embodiment of the present disclosure, as shown in FIG. 5, in order to increase ability of anti-extrusion of the liquid crystal display panel, liquid crystal display panel may further include a plurality of photoresist spacers (PS) 502 between the array substrate and the opposite substrate.

In practice, in the liquid crystal display panel according to the embodiments of the present disclosure, generally, other films or structures may also be provided on the opposite substrate, such as a common electrode layer, a protective layer and the like, which may have various embodiments and are not limited herein.

A process of manufacturing the above liquid crystal display panel will be described below in detail by giving an example of manufacturing the liquid crystal display panel as shown in FIG. 5. The process specifically includes the following steps:

(1) forming the array substrate structures as shown in FIGS. 4a˜4g in sequence by implementing the above method of manufacturing the array substrate;

(2) forming the protective layer, the black matrix 501, the common electrode layer (not shown in the drawing) and the photoresist spacer 502 in sequence on the base substrate 503 of the opposite substrate;

(3) aligning and assembling the base substrate 101 of the array substrate with the base substrate 503 of the opposite substrate to form a cell.

It is noted that in practice, step (1) and step (2) are not limited to be done in the order as described in the above process of manufacturing the liquid crystal display panel, that is, step (2) may be implemented firstly and then step (1) may be done, which is not limited herein.

Specifically, in step (3) of the above process of manufacturing the liquid crystal display panel according to the embodiment of the present disclosure, after the aligning and assembling the base substrate 101 of the array substrate with the base substrate 503 of the opposite substrate to form a cell, liquid crystal molecules may be filled into the assembled liquid crystal display panel by means of an immersing way; or, after step (1) of the forming the array substrate structures as shown in FIGS. 4a˜4g in sequence by implementing the above method of manufacturing the array substrate to obtain the above array substrate, liquid crystal molecules may be dropped and filled onto the base substrate 101 of the array substrate; or after step (2) of forming the protective layer (referring to FIG. 1), the black matrix 501, the common electrode layer (not shown in the drawing) and the photoresist spacer 502 in sequence on the base substrate 503 of the opposite substrate in the process of manufacturing the above liquid crystal display panel according to the embodiment of the present disclosure, liquid crystal molecules may be dropped and filled onto the base substrate 503 of the opposite substrate, which is not limited herein.

Based on the same inventive concept, embodiments of the present disclosure further provide a display device including the above liquid crystal display panel provided by the embodiments of the present disclosure. The display device may be a mobile phone, a tablet computer, a television, a display, a notebook computer, a digital photo frame, a navigator, a smart watch, a training wrist, a person digital assistant or any one of products or components having a display function. Embodiments of the display device may be implemented by referring to the above embodiments of the liquid crystal display panel and will not be repeatedly described.

The above array substrate and the method of manufacturing the same, the liquid crystal display panel and the display device according to the embodiments of the present disclosure include the base substrate, the data line disposed on the base substrate and the pixel electrode layer disposed on the layer in which the data line is located, wherein the pixel electrode layer includes the plurality of columns of pixel electrodes that are spaced apart from one another; the orthographic projection of the date line on the base substrate covers the orthographic projection of the gap between two adjacent columns of pixel electrodes on the base substrate, and the width of the data line is greater than the width of the gap between two adjacent columns of pixel electrodes. As the orthographic projection of the date line on the base substrate covers the orthographic projection of the gap between two adjacent columns of pixel electrodes on the base substrate and the width of the data line is greater than the width of the gap between two adjacent columns of pixel electrodes, a second electric field may be formed between the data line and the pixel electrode with the electrical field direction being directed from the array substrate to the opposite substrate, so as to control distortion of the liquid crystal and thus prevent light from leaking along the data line, and thus simultaneously, avoid need of black matrix to shielding light, thereby increasing aperture ratio.

Obviously, those skilled in the art may make modifications and changes on the embodiments of the present disclosure without departing from the spirit and scope of the present disclosure. As such, these modifications and changes should be included in the scope of the present disclosure if they fall into the scope of the claims and their equivalent of the present disclosure.

1. An array substrate, comprising: a base substrate, a data line disposed on the base substrate and a pixel electrode layer disposed above a layer in which the data line is located; wherein
the pixel electrode layer includes a plurality of columns of pixel electrodes that are spaced apart from one another; and
an orthographic projection of the data line on the base substrate covers an orthographic projection of a gap between two adjacent columns of pixel electrodes on the base substrate, and a width of the data line is greater than a width of the gap between the two adjacent columns of pixel electrodes.

2. The array substrate as claimed in claim 1, wherein the orthographic projection of the data line on the base substrate partially covers orthographic projections of the two adjacent columns of pixel electrodes on the base substrate.

3. The array substrate as claimed in claim 2, wherein the orthographic projection of the data line on the base substrate overlaps with orthographic projections of the two adjacent columns of pixel electrodes on the base substrate respectively in overlapping regions having a same width.

4. The array substrate as claimed in claim 1, further comprising a color filter layer between the layer in which the data line is located and the pixel electrode layer.

5. The array substrate as claimed in claim 4, further comprising a planarization layer between the color filter layer and the pixel electrode layer.

6. The array substrate as claimed in claim 1, further comprising: a gate line extending in a first direction and between the base substrate and the layer in which the data line is located; and a plurality of first common electrode lines and a plurality of second common electrode lines that are in a same layer as the gate line,
wherein the plurality of first common electrode lines extend in the first direction, the plurality of second common electrode lines extend in a second direction, and the first direction is perpendicular to the second direction.

7. The array substrate as claimed in claim 6, wherein the second common electrode lines are in one-to-one correspondence with the plurality of corresponding columns of pixel electrodes; and
an orthographic projection of each of the second common electrode lines on the base substrate is on a central line of an orthographic projection of a corresponding column of pixel electrodes on the base substrate.

8. A liquid crystal display panel, comprising: the array substrate as claimed in claim 1 and an opposite substrate disposed to be opposite to the array substrate.

9. The liquid crystal display panel as claimed in claim 8, wherein
the liquid crystal display panel further comprises a black matrix disposed on a side of the opposite substrate facing the array substrate.

10. (canceled)

11. A display device comprising the liquid crystal display panel as claimed in claim 8.

12. A method of manufacturing the array substrate as claimed in claim 1, the method comprising:
providing the base substrate;
forming the data line on the base substrate; and
forming the pixel electrode layer including the plurality of columns of pixel electrodes that are spaced apart from one another on the layer in which the data line is located.

13. The method as claimed in claim 12, further comprising:
before the forming the pixel electrode layer including the plurality of columns of pixel electrodes,
forming a color filter layer on the layer in which the data line is located.

14. The method as claimed in claim 13, further comprising:
before the forming the pixel electrode layer including the plurality of columns of pixel electrodes and after the forming the color filter layer,
forming a planarization layer on the color filter layer.

15. The method as claimed in claim 12, further comprising:
before the forming the data line on the base substrate,
simultaneously forming, on the base substrate, a gate line extending in a first direction and a plurality of first common electrode lines extending in a first direction and a plurality of second common electrode lines extending in a second direction, the first direction being perpendicular to the second direction;
the second common electrode lines are in one-to-one correspondence with the plurality of columns of pixel electrodes; and
an orthographic projection of each of the second common electrode lines on the base substrate is on a central line of an orthographic projection of a corresponding column of pixel electrodes on the base substrate.

16. The array substrate as claimed in claim 1, wherein the base substrate is a flexible base substrate and is made of polyvinylether phthalate, polyethylene naphthalate, polycarbonate, polyarylate, polyetherimide, polyethersulfone, polyimide or other plastic base plate.

17. The array substrate as claimed in claim 5, wherein the planarization layer is made of polyacrylic resin, polyepoxy-acrylic resin, photosensitive polyimide resin, polyester acrylic resin, polyurethane acrylate resin, phenolic epoxy acrylic resin or other organic insulating material.

18. The array substrate as claimed in claim 1, wherein the gate electrode and the drain and source electrodes is formed from materials including molybdenum, aluminum, tungsten, titanium, copper or an alloy combination thereof, the gate insulating layer and the passivation layer is formed from materials including silicon oxide, silicon nitride or a combination thereof, and the active layer is formed from a material including a polycrystalline silicon semiconductor material, an amorphous silicon semiconductor material, an oxide compound semiconductor material, or an organic semiconductor material.

19. The array substrate as claimed in claim 1, wherein the array substrate is a top gate array substrate or a bottom gate array substrate.

20. The liquid crystal display panel as claimed in claim 9, wherein the liquid crystal display panel further comprises a black matrix disposed on a side of the array substrate facing the opposite substrate, and the array substrate further includes a color filter layer disposed between the layer in which the data line is included and the pixel electrode layer, the black matrix being located at the gap between two adjacent color filters of the color filter layer.

21. The liquid crystal display panel as claimed in claim 20, wherein the black matrix disposed on the side of the array substrate facing the opposite substrate is formed by overlapping a red-light color filter and a blue-light color filter.
